(19) United States
(12) Patent Application Publication
(10) Pub. No.: US 2021/0242031 A1
(43) Pub. Date: Aug. 5, 2021

(54) METHOD FOR USING ULTRA-THIN ETCH STOP LAYERS IN SELECTIVE ATOMIC LAYER ETCHING

(71) Applicants: Tokyo Electron Limited, Tokyo (JP); University of Colorado Boulder, Boulder, CO (US)

(72) Inventors: Omid Zandi, Austin, TX (US); Paul Abel, Austin, TX (US); Jacques Faguet, Austin, TX (US); David Zywotko, Boulder, CO (US); Steven M. George, Boulder, CO (US)

(21) Appl. No.: 17/164,649

(22) Filed: Feb. 1, 2021

Related U.S. Application Data
(60) Provisional application No. 62/969,567, filed on Feb. 3, 2020.

(51) Int. Cl. H01L 21/311; H01L 21/02

(52) U.S. Cl. CPC H01L 21/31116; H01L 21/0228

(57) ABSTRACT

Method for selective etching of materials using an ultrathin etch stop layer (ESL), where the ESL is effective at a thickness as small as approximately one monolayer using atomic layer etching (ALE). A substrate processing method includes depositing a first film on a substrate, depositing a second film on the first film, and selectively etching the second film relative to the first film using an ALE process, where the etching self-terminates at an interface of the second film and the first film.

### CROSS-REFERENCE TO RELATED APPLICATIONS

This application claims priority to U.S. Provisional Patent Application No. 62/969,567, entitled, “METHOD FOR USING ULTRA-THIN ETCH STOP LAYERS IN SELECTIVE ATOMIC LAYER ETCHING,” filed Feb. 3, 2020; the disclosure of which is expressly incorporated herein, in its entirety, by reference.

### FIELD OF INVENTION

The present invention relates to the field of semiconductor manufacturing and semiconductor devices, and more particularly, to a method of using ultra-thin inorganic etch stop layers in semiconductor processing.

### BACKGROUND OF THE INVENTION

In the semiconductor and related industries, the fabrication of nanostructures and nanopatterns has resulted in demand for achieving near-atomic level accuracy and selectivity in depositing and etching different materials. Examples include metal filling of fine interconnect features, and formation of ultra-thin gate dielectrics and ultra-thin channels used in field-effect transistors and other nanodevices below the 10 nm scale. Atomic layer deposition (ALD) and atomic layer etching (ALE) processes can define the atomic layer growth and removal required for advanced semiconductor fabrication, producing ultrasmooth thin films based on deposit/etch-back methods and conformal etching in high-aspect-ratio structures.

### SUMMARY OF THE INVENTION

Methods for selective etching of materials using an ultrathin etch stop layer (ESL) is described, where the ESL is effective at a thickness as small as approximately one monolayer when using an ALE process.

According to one embodiment, a substrate processing method includes depositing a first film on a substrate, depositing a second film on the first film, and selectively etching the second film relative to the first film using an ALE process, where the etching self-terminates at an interface of the second film and the first film.

According to another embodiment, a substrate processing method includes providing a substrate containing a first film on a substrate and a second film on the first film, initiating etching of the second film using an ALE process that selectively etches the second film relative to the first film, and removing the second film using the ALE process, where the etching self-terminates at an interface of the second film and the first film. The method further includes, following the removing, etching the first film using an additional ALE process, where the ALE process includes alternating gaseous exposures of a first reactant and a second reactant, and the additional ALE process includes alternating gaseous exposures of a third reactant and a fourth reactant, and where the ALE process and the additional ALE process are performed without plasma excitation of the first reactant, the second reactant, the third reactant, and the fourth reactant. According to one embodiment, the first film has a uniform thickness of approximately one monolayer.

According to another embodiment, a substrate processing method includes depositing a ZrO₂ film on a substrate, depositing a Al₂O₃ film on the ZrO₂ film, initiating etching of the Al₂O₃ film using a thermal ALE process that selectively etches the Al₂O₃ film relative to the ZrO₂ film, and removing the Al₂O₃ film using the thermal ALE process, wherein the etching self-terminates at an interface of the Al₂O₃ film and the ZrO₂ film. According to one embodiment, the ZrO₂ film has a uniform thickness of approximately one monolayer. According to one embodiment, the thermal ALE process includes alternating gaseous exposures of HF and Al(CH₃)₃. According to one embodiment, the method further includes, following the removing, etching the ZrO₂ film using an additional thermal ALE process that includes alternating gaseous exposures of HF and Al(CH₃)₂Cl.

### DETAILED DESCRIPTION OF THE DRAWINGS

In the accompanying drawings:

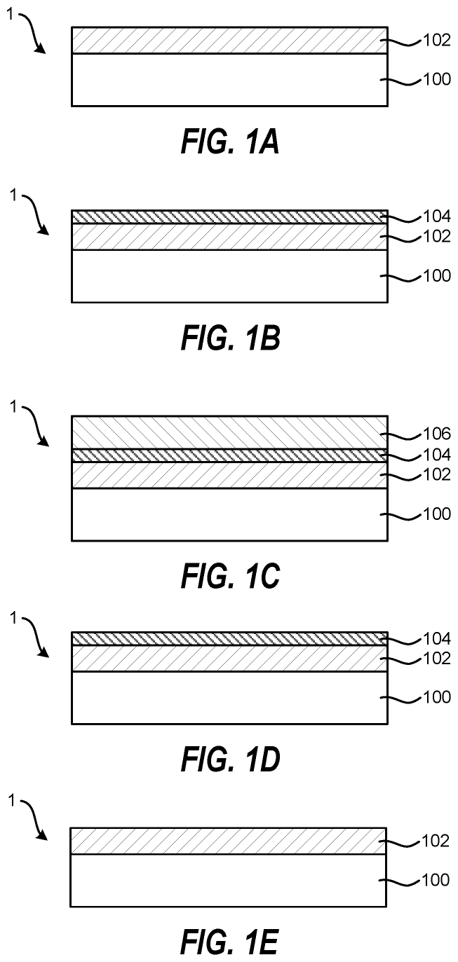

FIGS. 1A-1E schematically show a method of processing a layer structure according to an embodiment of the invention;

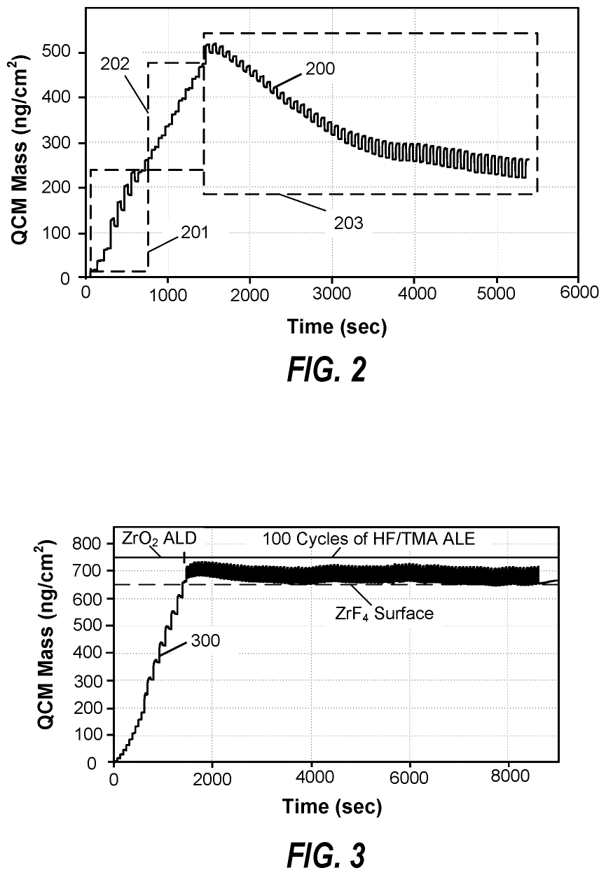

FIG. 2 shows a substrate mass change traced with a quartz crystal microbalance (QCM) during deposition/etch processes according to an embodiment of the invention;

FIG. 3 shows a substrate mass change traced with a QCM during deposition/etch processes according to embodiment of the invention;

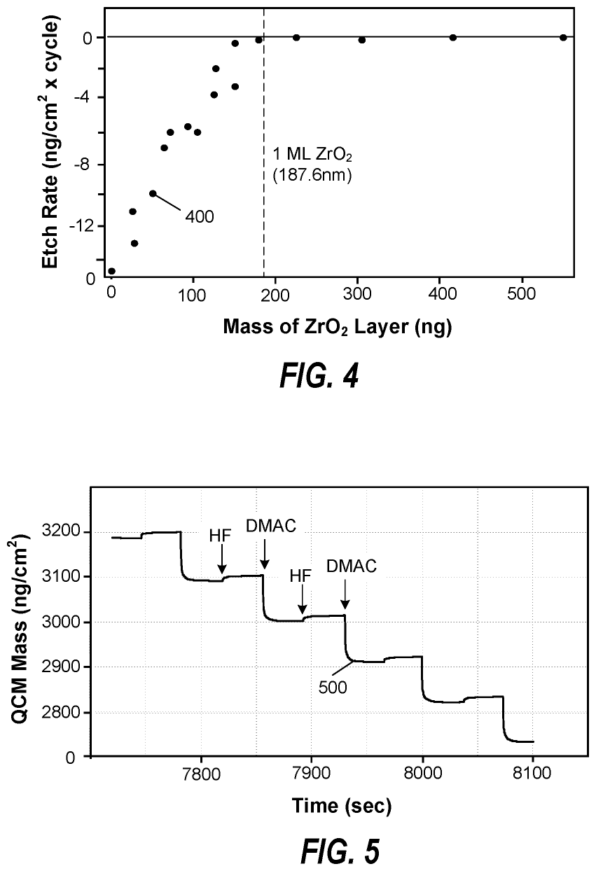

FIG. 4 shows etch rate measured by QCM according to an embodiment of the invention;

FIG. 5 shows a substrate mass change traced with a QCM during an ALE process according to embodiment of the invention; and

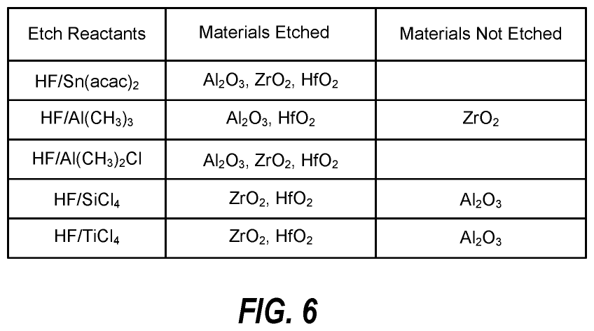

FIG. 6 shows in tabular form examples of combinations of etch reactants and materials that may be used for selective ALE according to embodiments of the invention.

### DETAILED DESCRIPTION OF SEVERAL EMBODIMENTS

In fabrication of semiconductor devices, an ESL is used in material stacks to stop an etch process at an interface of different materials or to protect an underlying material from etching. Embodiments of the invention describe the use of an ESL that may be only one monolayer (atomic layer) thick and may be deposited and later removed in-situ in one or more process chambers. The methods described herein can provide significant reduction in processing time and materials usage in semiconductor device manufacturing, and allow deposition/etch processes in nano-sized spaces and 3D features. Further, the methods can reduce problems associated with stress buildup during integration of multi-stacks of materials in semiconductor devices.

According to one embodiment, a method is described for selective etching of materials using an ultrathin ESL, where the ESL is effective in ALE processing at a thickness as small as approximately one monolayer. ALE is an etching technique for removing thin layers of material using sequential and self-limiting reactions. Thermal ALE, that is performed in the absence of plasma excitation, provides isotropic atomic-level etch control using sequential thermally driven reaction steps that are self-saturating and self-terminating. Thermal ALE etch mechanisms can include fluorination and ligand-exchange, conversion-etch, and oxidation and fluorination reactions. The etching accuracy can reach atomic-scale dimensions, and a large area of uniform substrate etching can be achieved. Examples of substrates that may be processed using the embodiments of the invention include thin wafers of a semiconductor material (e.g., Si) that are conventionally found in semiconductor manufacturing and can have diameter of 100 mm, 200 mm, 300 mm, or larger. However, other types of substrates may be used, for examples substrates for making solar panels.

FIGS. 1A-1E schematically show a method of processing a layer structure according to an embodiment of the invention. As schematically shown in FIG. 1A, the method includes providing a substrate 1 containing a base material 100 (e.g., a Si wafer), and a bottom film 102 on the base material 100. Although not shown in FIG. 1A, the substrate 1 may contain one or more additional films and materials and one or more simple or advanced patterned features.

In FIG. 1B, the method further includes depositing a first film 104 over the bottom film 102. According to embodiments of the invention, the first film 104 may serve as an ESL. In one example, the first film 104 is a dielectric film. In some examples, the first film 102 can include a metal oxide film with a general formula MₓO_{y}, where x and y are integers. Examples include ZrO₂ and Al₂O₃. In one example, the first film 104 can include ZrO₂ that may be uniformly deposited on the base material 100 using ALD processing. However, the first film 102 is not limited to metal oxides and may include or consist of other materials, for example oxides, nitrides, oxynitrides, and other materials found in semiconductor devices.

In FIG. 1C, the method further includes depositing a second film 106 on the first film 104, where the second film 106 contains a different material than the first film 104. According to embodiments of the invention, the first film 104 may be used to stop a subsequent etch process at an interface of the second film 106 and the first film 104 or to protect the first film 102 from etching. In one example, the second film 106 is a dielectric film. In some examples, the second film 106 can include a metal oxide film with a general formula MₓO_{y}, where x and y are integers. Examples include ZrO₂, HfO₂, and Al₂O₃. In one example, the second film 106 can include Al₂O₃ that may be uniformly deposited on the first film 104 using ALD processing. However, the second film 106 is not limited to metal oxides and may include or consist of other materials, for example oxides, nitrides, oxynitrides, and other materials found in semiconductor devices.

The method further includes initiating etching of the second film 106 using an ALE process (e.g., a thermal ALE process) that selectively etches the second film 106 relative to the first film 104. The ALE process removes the second film 106 until the etching self-terminates at the interface of the second film 106 and the first film 104 due to the selective etching characteristics of the ALE process. FIG. 1D schematically shows the substrate 1 when the second film 106 has been removed from the substrate 1. Thereafter, according to one embodiment, the first film 104 may be removed from the substrate 1, for example using an additional ALE process. This is schematically shown in FIG. 1D.

FIG. 2 shows a substrate mass change traced with a quartz crystal microbalance (QCM) during deposition/etch processes according to an embodiment of the invention. The mass trace 200 shows substrate mass gain/loss in ng/cm² on a QCM as a function of time, where mass gain and mass loss correspond to deposition and etch processes, respectively. The film structure included a bottom Al₂O₃ film, a ZrO₂ film on the bottom Al₂O₃ film, and a top Al₂O₃ film on the ZrO₂ film. The mass trace 200 is divided into three sections, where the first section 201 shows mass gain during ALD of the ZrO₂ film having a monolayer thickness on the bottom Al₂O₃ film, second section 202 shows mass gain during ALD of the top Al₂O₃ film on the ZrO₂ film, and third section 203 shows mass loss during etching and removal of the top Al₂O₃ film using an ALE process. The ALD of the ZrO₂ film was performed using alternating gaseous exposures of zirconium tetrachloride (ZrCl₄) and water (H₂O), and the ALD of the top Al₂O₃ film was performed using alternating gas exposures of trimethyl aluminum (Al(CH₃)₃) and H₂O. The ALE of the top Al₂O₃ film used alternating gas exposures of hydrogen fluoride (HF) and Al(CH₃)₃, where each ALD cycle included Al₂O₃ surface fluorination using a HF exposure, followed by exposure to Al(CH₃)₃, which resulted in etching of the fluorinated surface layer (i.e., AlF₃) through a ligand exchange reaction.

Unbalanced ALE reactions for etching of the top Al₂O₃ film include:

Al₂O₃+HF_{(g)}→AlF₃+H₂O_{(g)} (1)

AlF₃+Al(CH₃)_{3(g)}→AlFₓ(CH₃)_{y(g)} (2)

The etching of the top Al₂O₃ film proceeds until the top Al₂O₃ film is fully removed and then the ALE process self-terminates at the interface of the top Al₂O₃ film and the ZrO₂ film. The ALE process self-terminates because the ZrO₂ film is highly resistant to etching by the alternating gases exposures of HF and Al(CH₃)₃. Although the ZrO₂ film undergoes fluorination upon reaction with HF to form ZrF₄, the ligand exchange reaction with Al(CH₃)₃ is thermodynamically unfavorable under the ALE conditions and this disrupts and stops the etching process.

Unbalanced ALE reactions for the ZrO₂ film include:

ZrO₂+HF_{(g)}→ZrF₄+H₂O_{(g)} (3)

ZrF₄+Al(CH₃)_{3(g)}→no reaction (4)

The etch resistance of the ZrO₂ film is clearly shown in section 203 of FIG. 2, where, during removal of the top Al₂O₃ film, the measured mass trace 200 asymptotically approaches the mass of the ZrO₂ film after a large number of ALE cycles. Although fluorination of ZrO₂ is observed as a mass gain in each ALE cycle, following the subsequent exposure of the fluorinated surface to Al(CH₃)_{3(g)}, no net change in mass is observed, indicating a passive surface toward an exchange reaction. Thus, the etch process stops on the ZrO₂ film after fully etching and removing the top Al₂O₃ film, thereby demonstrating that the ZrO₂ film, although having only a monolayer thickness, acts as an ESL to effectively protect the underlying material (i.e., the bottom Al₂O₃ film) from etching. From a thermodynamic point of view, the etch blocking ability of the ZrO₂ film as an ESL can in theory be infinite as the ligand exchange reaction is thermodynamically unfavorable under the ALE conditions. This allows an ultra-thin ESL with a monolayer thickness to effectively block the ALE process by using a proper material as an ESL.

FIG. 3 shows substrate mass change traced with a QCM during deposition/etch processes according to embodiment of the invention. The trace 300 shows mass gain during ALD of a ZrO₂ film using alternating gas exposures of ZrCl₄ and H₂O, and mass change during subsequent ALE processing of the ZrO₂ film using alternating gas exposures of HF and Al(CH₃)₃. The robustness of the ZrO₂ film as an ESL is clearly demonstrated and shows a 100% blocking efficiency of the ZrF₄ surface of the ZrO₂ film, even after 100 cycles of the ESL process.

FIG. 4 shows etch rate measured by QCM according to embodiment of the invention. The etch rate of an Al₂O₃ film in an ALE process as a function of different amounts of ZrO₂ pre-deposited on the Al₂O₃ film is shown in the figure. The ZrO₂ was deposited by ALD using alternating gas exposures of Al(CH₃)₃ and H₂O, and the ALE process was performed using alternating gas exposures of HF and Al(CH₃)₃. The experimental data in solid circles 400 shows that increasing amount of ZrO₂ deposited on the Al₂O₃ film resulted in reduced amount of etching of the underlying Al₂O₃ film. Particularly, about 200 ng of ZrO₂, which corresponds to approximately one monolayer of ZrO₂ deposited on the Al₂O₃ film, reduced the Al₂O₃ etch rate to approximately zero value. Increasing the thickness of the ZrO₂ film to above a monolayer thickness did not affect the etch rate, since the ZrO₂ already fully covered the Al₂O₃ film. The effective etch stopping at a thickness of only approximately one monolayer of ZrO₂ is in agreement with the unfavorable thermodynamics of the etch reaction, where Al₂O₃ surface reaction sites are passivated with ZrO₂. Further, the effective etch blocking of ZrO₂ at a thickness of approximately one monolayer shows that the first monolayer of ZrO₂ uniformly covers the Al₂O₃ film and that the ZrCl₄ precursor is more reactive towards exposed Al₂O₃ surface sites than the ZrO₂ covering the Al₂O₃ film.

FIG. 5 shows a substrate mass change traced with a QCM during an ALE process according to embodiment of the invention. Although a ZrO₂ film is not etched by thermal ALE processing that etches a Al₂O₃ film using alternating gas exposures of HF and Al(CH₃)₃, the ZrO₂ film may be etched and removed by replacing one or more of the gaseous etch reactants in the ALE processing. In FIG. 5, a ZrO₂ film was etched, as shown in trace 500, by thermal ALE processing using alternating gas exposures of HF and dimethyl aluminum chloride (DMAC, Al(CH₃)₂Cl). Replacing Al(CH₃)₃ with Al(CH₃)₂Cl renders the ligand exchange reaction thermodynamically favorable and thereby enables etching of the ZrO₂ film according the following unbalanced ALE reactions:

ZrO₂+HF_{(g)}→ZrF₄+H₂O_{(g)} (5)

ZrF₄+Al(CH₃)₂Cl_{(g)}→ZrFₓCl_{y(g)} (6)

The etching of the ZrO₂ film is illustrated by the stepwise mass loss in the QCM trace.

FIG. 6 shows in tabular form examples of combinations of etch reactants and materials that may be used for selective ALE according to embodiments of the invention. The listed combinations are based on experimental and thermodynamic information. In one example illustrated in FIG. 6, a ZrO₂ film may be used as an ESL for thermal ALE processing of Al₂O₃ and HfO₂ films using alternating gaseous exposures of HF and Al(CH₃)₃. Thereafter, if desired, the ZrO₂ film may be removed using alternating gaseous exposures of HF and Al(CH₃)₂Cl, for example. In another example, an Al₂O₃ film may be used as an ESL for thermal ALE processing of ZrO₂ and HfO₂ films using alternating gaseous exposures of HF and SiCl₄. Thereafter, if desired, the Al₂O₃ film may be removed using alternating gaseous exposures of HF and Al(CH₃)₃, for example.

According to some embodiments, the ALD processing, the ALE processing, or both, may be performed at a substrate temperature between about 100° C. and about 400° C., between about 200° C. and about 400° C., or between about 200° C. and about 300° C. In one example, the ALD processing, the ALE processing, or both, may be performed at a substrate temperature between about 250° C. and about 280° C.

In some examples, the ALD processing and the ALE processing may be performed at the same substrate temperature or at approximately the same substrate temperature. Those skilled in the art will readily appreciate that this allows for high substrate throughput when performing both the ALD processing and the ALE processing in the same process chamber, and when using different process chambers for the ALD processing and the ALE processing.

In some examples, two or more of the ALD processing, the ALE processing, and the additional ALE processing may be performed at that same substrate temperature or at approximately the same substrate temperature. For example, the ALE processing and the additional ALE processing may be performed at the same substrate temperature or at approximately the same substrate temperature.

A plurality of embodiments for a method for selective etching of materials using an ultrathin etch stop layer (ESL) have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A substrate processing method, comprising:
depositing a first film on a substrate;
depositing a second film on the first film; and
selectively etching the second film relative to the first film using an atomic layer etching (ALE) process, wherein the etching self-terminates at an interface of the second film and the first film.

2. The method of claim 1, wherein the ALE process includes alternating gaseous exposures of a first reactant and a second reactant.

3. The method of claim 2, wherein the ALE process includes a thermal ALE process that is performed without plasma excitation of the first reactant and the second reactant.

4. The method of claim 1, wherein the first and second films are dielectric films.

5. The method of claim 1, wherein the first and second films include different metal oxide films that are selected from the group consisting of Al₂O₃, ZrO₂, and HfO₂.

6. The method of claim 1, wherein the second film includes an Al₂O₃ film.

7. The method of claim 6, wherein the Al₂O₃ film is deposited using alternating gas exposures of Al(CH₃)₃ and H₂O in an atomic layer deposition (ALD) process.

8. The method of claim 1, wherein the ALE process includes alternating gaseous exposures of 1) HF and 2) Sn(acac)₂, Al(CH₃)₃, Al(CH₃)₂Cl, SiCl₄, or TiCl₄.

9. The method of claim 1, wherein the first film includes a ZrO₂ film.

10. The method of claim 9, wherein the ZrO₂ film has a uniform thickness of approximately one monolayer.

11. The method of claim 9, wherein the ZrO₂ film is deposited using alternating gas exposures of ZrCl₄ and H₂O in an atomic layer deposition (ALD) process.

12. The method of claim 1, further comprising:
following the removing, etching the first film using an additional ALE process.

13. The method of claim 12, wherein the ALE process includes alternating gaseous exposures of a first reactant and a second reactant, and the additional ALE process includes alternating gaseous exposures of the first reactant and a third reactant that is different than the second reactant.

14. The method of claim 13, wherein the ALE process and the additional ALE process are performed without plasma excitation of the first reactant, the second reactant, and the third reactant.

15. The method of claim 13, wherein the first film includes a ZrO₂ film, the second film includes an Al₂O₃ film, the first reactant includes HF, the second reactant includes Al(CH₃)₃, and the third reactant includes Al(CH₃)₂Cl.

16. A substrate processing method, comprising:
providing a substrate containing a first film on a substrate and a second film on the first film;
initiating etching of the second film using a thermal atomic layer etching (ALE) process that selectively etches the second film relative to the first film;
removing the second film using the ALE process, wherein the etching self-terminates at an interface of the second film and the first film; and
following the removing, etching the first film using an additional ALE process, wherein the ALE process includes alternating gaseous exposures of a first reactant and a second reactant, and the additional ALE process includes alternating gaseous exposures of the first reactant and a third reactant that is different than the second reactant, and wherein the ALE process and the additional ALE process are performed without plasma excitation of the first reactant, the second reactant, and the third reactant.

17. A substrate processing method, comprising:
depositing a ZrO₂ film on a substrate;
depositing a Al₂O₃ film on the ZrO₂ film;
initiating etching of the Al₂O₃ film using a thermal atomic layer etching (ALE) process that selectively etches the Al₂O₃ film relative to the ZrO₂ film; and
removing the Al₂O₃ film using the thermal ALE process, wherein the etching self-terminates at an interface of the Al₂O₃ film and the ZrO₂ film.

18. The method of claim 17, wherein the thermal ALE process includes alternating gaseous exposures of HF and Al(CH₃)₃.

19. The method of claim 17, wherein ZrO₂ film has a uniform thickness of approximately one monolayer.

20. The method of claim 17, further comprising:
following the removing, etching the ZrO₂ film using an additional thermal ALE process that includes alternating gaseous exposures of HF and Al(CH₃)₂Cl.
